(19) United States
(12) Patent Application Publication
(10) Pub. No.: US 2002/0024835 A1
(43) Pub. Date: Feb. 28, 2002

(54) Non-volatile passive matrix device and method for readout of the same

(76) Inventors: Michael O. Thompson, Ithaca, NY (US); Richard Womack, Albuquerque, NM (US); Johan Carlsson, Linkoping (SE); Goran Gustafsson, Linkoping (SE)

Correspondence Address: BIRCH STEWART KOLASCH & BIRCH, PO BOX 747, FALLS CHURCH, VA, 22040-0747, US

(21) Appl. No.: 09/899,096

(22) Filed: Jul. 6, 2001

(30) Foreign Application Priority Data
Jul. 7, 2000 (NO) 20003508
Jul. 24, 2000 (NO) 20004236

(51) Int. Cl. G11C 11/22

(52) U.S. Cl. 365/117

(57) ABSTRACT

In a non-volatile passive matrix memory device comprising an electrically polarizable dielectric memory material exhibiting hysteresis between first and second sets of addressing electrodes, the electrodes of the first set are word lines and the electrodes of the second set are bit lines of the memory device. A memory cell with a capacitor-like structure is defined in the memory material at the overlap between a word line and a bit line. The word lines are divided into segments with each segments sharing and being defined by adjoining bit lines and means are provided for connecting each bit line of a segment with a sensing means, thus enabling simultaneous connections of all memory cells of a word line segment for readout via the bit lines of the segment. Each sensing means senses the charge flow in a bit line in order to determine a logical value stored in a memory cell defined by the bit line. In a readout method for a memory device of this kind a word line of a segment is activated according to a protocol by setting its potential to a switching voltage of the memory cell during at least a portion of a read cycle, while keeping the bit lines of the segment at zero potential, during which read cycle a logical value stored in the individual memory cells is sensed by the sensing means.

Use in a volumetric data storage apparatus with a plurality of stacked layers which each comprises a non-volatile passive matrix memory device.

The present invention concerns a non-volatile passive matrix memory device comprising an electrically polarizable dielectric memory material exhibiting hysteresis, particularly a ferroelectric material, wherein said memory material is provided sandwiched in a layer between a first set and second set of respective parallel addressing electrodes, the electrodes of the first set constituting word lines of the memory device and being provided in substantially orthogonal relationship to the electrodes of the second set, the latter constituting bit lines of the memory device, wherein a memory cell with a capacitor-like structure is defined in the memory material at crossing between word lines and bit lines, wherein the memory cells of the memory device constitute the elements of the passive matrix, wherein each memory cell can be selectively addressed for a write/read operation via a word line and bit line, wherein write operation to a memory cell takes place by establishing a desired polarization state in the cell by means of a voltage being applied to the cell via the respective word line and bit line defining the cell, said applied voltage Vs either establishing a determined polarization state in the cell or being able to switch the cell between the polarization states thereof, and wherein a read operation takes place by applying a voltage smaller than the switching or polarization voltage Vs to the cell and detecting at least one electrical parameter of an output current on the bit lines; and a method for addressing a memory device of this kind, wherein the method comprises steps for controlling electric potentials on all word lines and bit lines in a time-coordinated fashion according to a protocol comprising electric timing sequences for all word lines and bit lines, arranging said protocol to comprise a read cycle, and providing during the read cycle for sensing means to sense charges flowing in the bit lines.

The invention also concerns the use of a non-volatile passive matrix memory device in a volumetric data storage apparatus.

Ferroelectric integrated circuits have revolutionary properties compared to conventional technology. Applications include non-volatile information storage devices, in particular matrix memories having advantages such as high speed, virtually unlimited endurance and high write speed; properties recently only dreamed of.

Ferroelectric matrix memories can be divided into two types, one type containing active elements linked to the memory cells and one type without active elements. These two types will be described below.

A ferroelectric matrix memory having memory cells in the form of ferroelectric capacitors without active access elements such as an access transistor comprises a thin ferroelectric film with a set of parallel conducting electrodes (“word lines”) deposited on one side and an essentially orthogona set of conducting electrodes (“bit lines”) deposited on the other side, which configuration is in the following referred to as a “passive matrix memory”. In the passive matrix memory, individual ferroelectric memory cells are formed at the crossing points of the opposing electrodes creating a memory matrix comprising memory cells that can be individually accessed electrically by selective excitation of the appropriate electrodes from the edge of the matrix

Another approach for providing a matrix memory is to modify each ferroelectric memory cell by including an active element, typically an access transistor in series with the ferroelectric capacitor. The access transistor controls the access to the capacitor and blocks unwanted disturb signals for instance from neighbouring memory cells. The memory cell can typically include a ferroelectric capacitor and a n-channel metal-oxide-semiconductor field-effect transistor (in the following generically abbreviated “MOSFET” without indicating n-type or p-type for sake of simplicity) having its gate connected to a word line. A source/drain region of the MOSFET is connected to a bit line. One electrode of the ferroelectric capacitor is connected to the source/drain region of the MOSFET and the other electrode of the capacitor is connected to a so-called “drive line”. This is the conventional concept of today and is often provided as one transistor, one capacitor (1T-1C) memory cells. Other concepts are also well-known, including two transistors or more. However, all these concepts increase the number of transistors compared to the passive matrix memory, which implies a number of drawbacks such as decreasing the number of memory cells within a given area, which increasing the complexity. Herein, these types of devices are in the following referred to as “active” matrix memories because of the “active” element, i. e. the transistor in each memory cell.

The present invention is, however, solely directed towards passive matrix memories without active elements, such as diodes or transistors that are locally associated to the memory cell.

Read and write operations of passive matrix memories may be performed by means of a so-called “partial word addressing”, whereby only a portion, typically one of the memory cells on a given word line are read (or written). To accomplish such a partial read (or write) operation the non-addressed cells on non-activated word lines or bit lines are voltage biased according to a so-called “pulsing protocol” in order to avoid partial switching of the non-addressed cells. The choice of pulsing protocol depends on a number of factors, and different schemes have been proposed in the literature for applications involving ferroelectric memory materials exhibiting hysteresis. This is described for instance in the present applicant's co-pending Norwegian patent application No. 20003508 filed on Jul. 7, 2000, from which the present application claims priority. This application describes a protocol for a passive matrix memory. On the other hand, normally the biasing of the non-addressed cells causes disturb voltages, which can result in loss of memory content or give rise to leakage currents and other parasitic currents, here called “sneak currents”, which can mask the current of an addressed memory cell during a read operation and thereby mask the data content during the read. Depending on the type of device in question, different criteria for avoiding or at least reducing disturbance of non-addressed memory cells can be defined, such as methods for sneak current cancellation, Another way is to lower the sensitivity of each cell in the matrix to small-signal disturbances, which can be achieved by cells that exhibit a non-linear voltage-current response, involving e.g. thresholding, rectification and/or various forms of hysteresis.

In order to improve the performance of both active and passive ferroelectric memory devices, the memory matrix can be internally divided, “segmented”, into smaller blocks, so-called “segments”, for instance to reduce power requirements. Normally this segmentation is transparent to a user. Another reason for segmentation is the problem with ferroelectric capacitors that they suffer from a so-called “fatigue”, which means that after a ferroelectric capacitor has been switched a large number of times, say several millions, it cannot hold a remnant polarization and thereby stops functioning. A solution to this particular problem can be smaller matrix segments to avoid switching an entire row of capacitors. This is disclosed for instance in U.S. Pat. No. 5,567,636 Another document describing a segmented memory matrix is Gary F. Derbenwick & al., “Non-volatile Ferroelectric Memory for Space Applications”, Celis Semiconductor Corporation, Colorado Springs. This document describes a segmented memory matrix able to reduce power requirements in an active matrix using one transistor, one capacitor memory cell architecture (1T, 1C).

Examples of passive matrix memories employing ferroelectric memory substances can be found in the literature dating back 40-50 years. For instance, W. J. Merz and J. R. Anderson described a barium titanate based memory in 1955 (W. J. Merz and J. R. Anderson, “Ferroelectric storage devices”, Bell. Lab. Record. 1, pp. 335-342 (1955)), and similar work was also reported by others promptly thereafter (see, e.g. C. F. Pulvari “Ferroelectrics and their memory applications”, IRE Transactions CP-3, pp. 3-11 (1956), and D. S. Campbell, “Barium titanate and its use as a memory store”, J. Brit. IRE 17 (7), pp. 385-395 (1957)). Another example of a passive matrix memory can be found in IBM Technical Disclosure Bulletin Vol. 37, No. 11, November 1994. However, none of these documents describe a solution to the problem with disturbing non-addressed cells.

Another approach to remedy the problem would be to modify the ferroelectric material in order to create a square-like hysteresis loop. However, also this has not yet been described in more detail.

Accordingly, there is a need of a passive matrix memory without the above negative attributes, such as disturbed non-addressed cells.

In the light of the above, it is an object of the invention to provide a passive matrix memory device, which solves the problem with disturbed non-addressed memory cells. Another object of the invention is to provide a passive matrix memory device which minimizes the influence of cumulative signals from non-addressed cells during reading of stored data. Finally there is also an object of the invention to provide a readout method in a passive matrix memory device and compatible with the above-mentioned objects.

The above objects as well as further advantages and features are realized with a non-volatile passive memory matrix device according to the invention which is characterized in that the word lines are divided into a number of segments, each segment sharing and being defined by a plurality of adjoining bit lines in the matrix, and that means are provided for connecting each bit line assigned to a segment with an associated sensing means, thus enabling the simultaneous connection of all memory cells assigned to a word line on a segment for readout via the corresponding bit lines of the segment, each sensing means being adapted for sensing the charge flow in the associated bit line in order to determine a logical value stored in the memory cell defined by the bit line.

In a first advantageous embodiment of the memory device according to the invention the means for simultaneous connection of each bit line of a segment with associated sensing means during addressing are multiplexers. In that case the number of multiplexers may correspond to the largest number of bit lines defining a segment, each bit line of a segment being connected with a specific multiplexer. It is then preferred that the output of each multiplexer is connected with a single sensing means, and particularly the single sensing means can then be a sense amplifier.

In a second advantageous embodiment of the memory device according to the invention the means for simultaneous connection of each bit line of a segment to an associated sensing means during addressing is a gate means. In that case all the bit lines of a segment can be connected with a specific gate means, each gate means having a number of outputs corresponding to the number of bit lines in the respective segment, and each output of each gate means is connected with a specific bus line of an output data bus, the number of bus lines thus corresponding to largest number of bit lines in a segment, and each bus line is connected with a single sensing means.

Preferably the gate means then comprises pass gates and preferably the sensing means is a sense amplifier.

The above objects and other advantages and features are also realized with a readout method for a memory device according to the invention, whereby the method is characterized by connecting each bit line within a word line segment with an associated sensing means, activating according to the protocol one word line of the segment at a time by setting the potential of said one word line of the segment to the switching voltage Vs during at least a portion of the read cycle, while keeping all bit lines of the segment at zero potential and determining the logical value stored in the individual cells sensed by the sensing means during the read cycle.

In an advantageous embodiment readout method according to the invention, each bit line within a word line segment is connected with an associated sensing means, all word lines and bit lines, when no cell is read or written, are kept at a quiescent voltage of approximately Vs/3, one word line of the segment is activated at a time according to the protocol by setting the potential of said one word line of the segment to the switching voltage Vs during at least a portion of the read cycle, while keeping all bit lines of the segment at zero potential, and determining the logical value stored in the individual cells sensed by the sensing means during the read cycle.

Finally, the above objects and other features and advantages are also achieved according to the invention with the use of the inventive non-volatile passive memory device and the inventive method for readout in a volumetric data storage apparatus with a plurality of stacked layers, each layer comprising one of the non-volatile passive matrix memory devices.

The invention shall now be more fully described on the basis of discussions of its general background and preferred embodiments presented hereinafter, when read in conjunction with the appended drawing figures, wherein

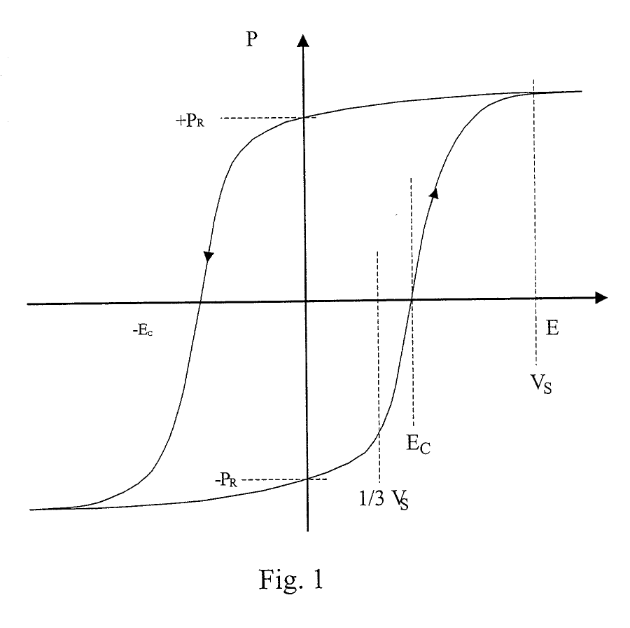

FIG. 1 shows a principle drawing of a hysteresis curve for a ferroelectric memory material;

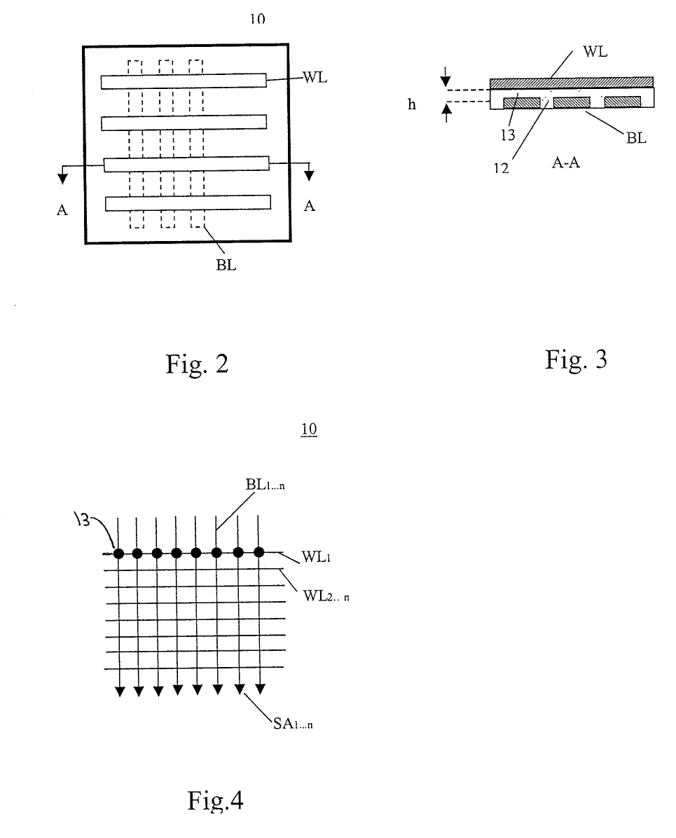

FIG. 2 a schematic diagram of a portion of a passive memory matrix with crossing electrode lines and with the memory cells containing a ferroelectric material localized between these electrodes where they overlap;

FIG. 3 an enlarged cross-sectional view taken along line A-A in FIG. 2;

FIG. 4 a functional block diagram illustrating full word read in a ferroelectric matrix memory;

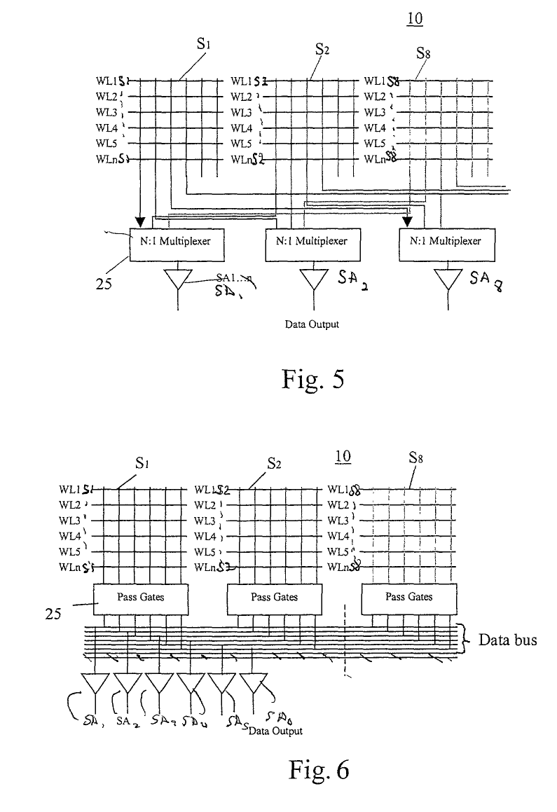

FIG. 5 a functional block diagram illustrating a passive matrix memory having segmented word lines to improve readout of memory cells, and according to preferred embodiment of the invention;

FIG. 6 a functional block diagram illustrating a passive matrix memory having segmented word lines to improve readout of memory cells, and according to preferred embodiment of the invention;

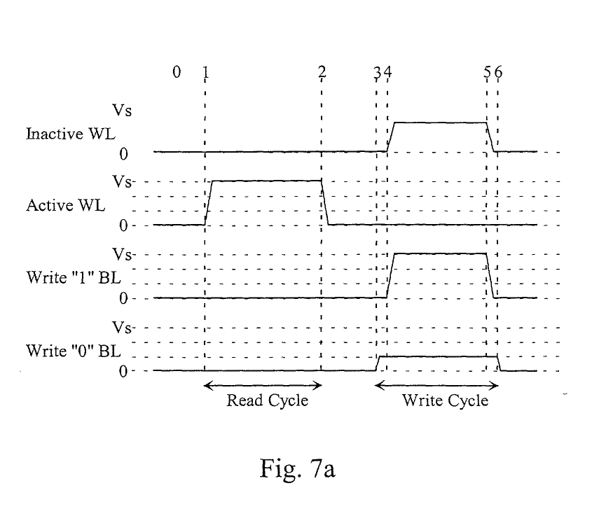

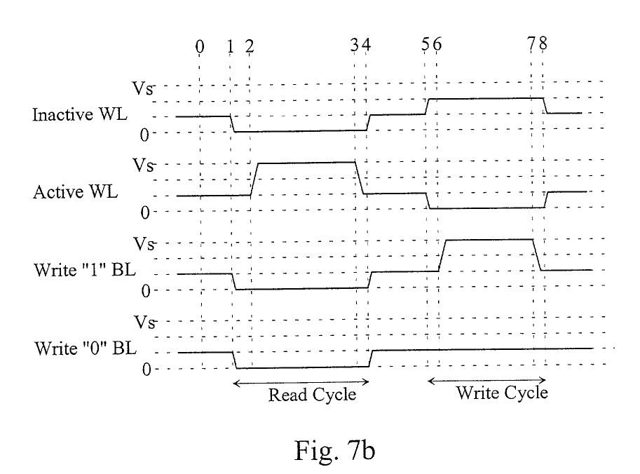

FIG. 7a a simple full word read timing diagram with a following write/refresh cycle provided for addressing a word line of a segment of the memory matrix in “full word read”;

FIG. 7b a variant of the timing diagram in FIG. 7a; and

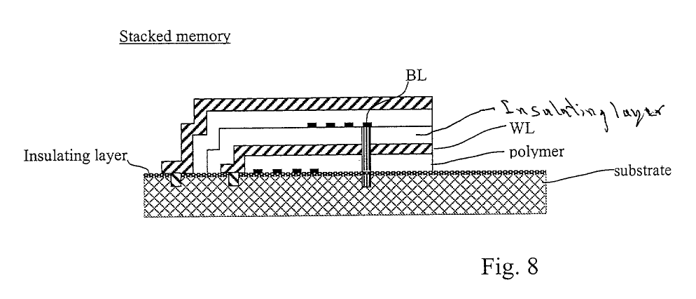

FIG. 8 schematically how the memory matrix in FIG. 5 or 6 can be implemented in a volumetric memory device.

Before giving a detailed description of preferred embodiments, the general background of the present invention shall be discussed in order to give a better understanding of how a passive matrix memory, or even a single memory cell in such a memory works. In this connection reference is made to FIG. 1, which shows a typical so-called “hysteresis loop” of a ferroelectric material, whereas the polarization P of the ferroelectric material is plotted versus the electric field E. The value of the polarization will travel around the loop in the direction indicated. A ferroelectric material with a hysteresis loop as shown in FIG. 1 will change its net polarization direction (“switch”) upon application of an electric field E that exceeds a so-called coercive electric field E_{c}. As the electric field E exceeds the coercive electric field E_{c}, the polarization P changes abruptly to a large positive value +Pᵣ (assuming starting at negative polarization at zero electric field). This positive polarization +Pᵣ remains until a large negative electric field exceeding a negative coercive electric field −E_{c} changes the polarization again back to negative polarization. In this way, memory devices provided with capacitors comprising ferroelectric material will exhibit a memory effect in the absence of an applied external electric field, making it possible to store non-volatile data by application a potential difference across the ferroelectric material, which evokes a polarization response, the direction (and magnitude) thereof may thus be set and left in a desired state. Likewise, the polarization status can be determined. Storing and determining data will be described in more detail below.

Depending on the required switching speed etc., a nominal voltage Vₛ employed for driving the polarization state of the ferroelectric material is typically selected considerably larger than the coercive voltage E_{c}. The nominal voltage Vₛ is generically illustrated with a dashed line in FIG. 1, but is by no means limited to this particular value. Other values can be applicable.

FIG. 2 illustrates a portion of a memory matrix 10 of a passive matrix memory 11 showing two to each other opposing sets of parallel electrodes: word line electrodes WL and bit line electrodes BL. The word line and the bit line electrodes WL;BL are arranged perpendicular to each other, whereby at the intersecting areas, they define side-walls of certain volume elements of an insulating ferroelectric material (described in more detail below) defining the volume of capacitor-like memory cells in the memory matrix 10. Now it is referred to FIG. 3, which is an illustration of a cross-sectional view along line A-A in FIG. 2a. The dielectric of each “capacitor” is the ferroelectric material in a ferroelectric layer 12, where the thickness of the material defines the height h of the volume elements defining the memory cells 13. For reasons of simplicity, only three crossing points between the word line and bit line electrodes WL:BL are illustrated in this FIG. 2.

By application of a potential difference Vₛ between two opposing electrodes, the word line WL and the bit line BL in a cell 13, the ferroelectric material in the cell 13 is subjected to an electric field E which evokes a polarization response, having a direction which may be set and left in one of two stable states, positive or negative polarization, according to what is described for instance in FIG. 1. The two state represent the binary states of “1” and “0”. Likewise, the polarization status in the cell 13 may be altered or deduced by renewed application of a potential difference between the two opposing electrodes WL and BL addressing that cell 13, which either causes the polarization to remain unchanged after removal of the potential difference or to flip to the opposite direction. In the former case, a small current will flow in response to the applied voltage, while in the latter case the polarization change causes a large current. The current is compared to a reference, which can be provided in many ways (not shown), to be able to decide if it was a “0” or a “1”. The read is always a destructive read ending up in a “0” and the memory cell must therefore be restored to its initial state (since a “1” or a “0” always ends up in a “0” because of the destructive read). A more detailed description of how a passive matrix memory operates will be given in below when describing a preferred embodiment of the invention.

Also in order to improve the understanding of the present invention, reference can be made to FIG. 4 illustrating another readout method for passive matrix memories, hereinafter called “full word read”, whereby an active word line, herein the first word line WL₁ comprising a desired memory cell 13, is sensed over its entire word length. Full word read per se is a known concept described for instance in U.S. Pat. No. 6,157,578. In said document, however, the solution is directed to an active matrix memory device, with the purpose of increasing the speed of transferring data stored in a relatively large block of a memory matrix. The present invention is on the contrary related to passive matrix memories, whereby prior art knowledge regarding active matrices, such as described in U.S. Pat. No. 6,157,578, is not relevant since active devices does not have the problem with disturbing non-addressed cells.

It is important to notice that according to the pulsing protocol for full word read in a passive matrix memory, unused word lines, in this case the second to the n.th word lines WL_{2..n} can be maintained at the same potential (or essentially the same) as the bit lines BL_{1..n}. Consequently, there is no disturbing signal on any of the non-addressed cells of the memory matrix 10. For readout of data (sensing), the active word line, in this case the first word line WL₁, is brought to a potential causing current I to flow through the cells on the crossing bit lines BL_{1..n.} The magnitude of the current I depends on the polarization state in each cell 13 and are determined by sense amplifiers SA_{1..n}, one for each bit line BL_{1..n} as shown in FIG. 4.

The full word read method provides several advantages such as: that the readout voltage may be chosen much higher than the coercive voltage without incurring partial switching in non-addressed cells, and that it is compatible with a large matrix.

The preferred embodiments of the present invention are illustrated in FIGS. 5-7 of the drawings. An accompanying timing diagram that accomplish 0V disturb of non-addressed memory cells while providing the switching voltage Vₛ on all cells of the active word line WL₁ during reading of all cells in an active segment is shown in FIG. 7a and yet another one in FIG. 7b.

With reference now to FIG. 5, a passive ferroelectric matrix memory according to a first preferred embodiment of the invention provided as a 16 Megabit (16 Mb) memory matrix arranged as 256 kilobits by eight organization (256 Kb×8), or in other words, 256 thousand word lines of 64 bits is illustrated. Other organizations including ×9, ×16, ×18, ×32, or the like are also possible memory architectures. In FIG. 5, there are 6 word lines WL₁ . . . WLₙ shown. Other word lines are included within the memory matrix 10 but are not shown. Each word line WL₁ . . . WLₙ is divided into eight (of which only three are shown) segments S₁, S₂ . . . S₈ of eight bits each, which means that the word length is eight bits (eight memory cells). The word lines WL corresponding to the first word line segment S1 are labelled WL_{1S1}, WL_{2S1} . . . WL_{nS1}. For simplicity, the bit lines BL are not labelled. Unlike conventional passive matrix memories employing partial word read, all memory cells within a word line segment are connected simultaneously to sense amplifiers SA_{1..n}.

Data stored or to be stored in the memory matrix 10 is accessible by means of an associated row decoder and column decoder (not illustrated in this figure) The data maintained within the memory cells of the memory matrix 10 is read out according to a pulsing protocol, with reference to FIG. 6a by means of a number of sense amplifiers SA_{1..n} coupled to the bit lines.

All of the bit lines (of which two are indicated with arrows) from one word line segment (in this case the first segment) S₁ are routed to different multiplexers 25, and simultaneously selected when the given word line WL₁ is active. In this manner, all bit lines of the first word line in the segment S₁ are simultaneously read in the “full word configuration”, while maintaining shared usage of a sense amplifier array comprising sense amplifiers SA_{1..n} through the multiplexers 25.

The matrix memory 10 illustrated in FIG. 5 comprises three word line segments S_{1..3}. Preferably, the matrix memory is provided with n multiplexers 25 and a corresponding number of segments S_{1..n}.

According to a preferred embodiment of the invention, the number of memory cells is at least 256 cells per segment. Coupled with 32:1 multiplexers M_{1..n} this permits an 8192 bits wide memory with only 32 duplications of the word-line drivers. Each word line WL is segmented according to the number of sense amplifiers SA_{1..n} provided. All of the bit lines BL from one word-line segment S_{1..n} are routed to multiplexers 25, and simultaneously selected when the given word line WL is active. In this manner, all bit lines BL of the word-line segment 10 are simultaneously read in the “full word configuration”, while maintaining the shared usage of the sense amplifier array SA_{1..n} through the multiplexers 25.

In FIG. 6, there is shown an alternative embodiment of the present invention, wherein the multiplexers are substituted by gate means. The gate means enable the bit lines in the same way as the above-described multiplexers.

Preferably, the gate means is a pass gate, preferably arranged under the capacitors making up the matrix.

FIGS. 7a and 7b depict alternative timing diagrams for a full word read cycle.

FIG. 7a illustrates a full word read timing diagram with a following write/read refresh cycle for a word line segment. This timing diagram is based on a four-level voltage protocol. According to this timing diagram all word and all bit lines are, when no cell in the matrix is read or written, kept at a quiescent voltage equal to zero volts. All memory cells having an addres represented by the crossings formed by an activated word line and by all bit lines within this segment which are to be read.

The inactive word lines WL and all bit lines BL follow the same potential curves during the read cycle. During the read cycle the word line contacting the cells to be read is set to switching voltage V_{S}. At the same time interval all bit lines are kept at zero voltage. In the illustrated timing diagram it is provided that application of the switching voltage V_{S} on the word line side of a cell and a zero voltage on the bit line side of the same cell implies that a “0” is written into the cell. According to this, in both timing diagrams shown all cells on the active word lines are set into the zero-state after the read operation performed. Therefore, to restore data of the memory, it will be necessary to write back “1” only on the bit lines that has cells that should contain “1”. This is illustrated in both examples of FIGS. 7a and 7b, where reversed polarity of the voltage is applied on the “write 1” cells during the read cycle as indicated in the figures.

FIG. 7b illustrates an alternate timing diagram based on a four-level voltage protocol. According to this embodiment all word lines and bit lines are, when no cell in the matrix is read or written, kept at a quiescent voltage Vs/3.

The exact values for all timing points illustrated as examples in FIGS. 7a and 7b are dependent on the materials of the memory cells and on details in the design. The time intervals 2-1, 4-3 in FIG. 7b, can for instance be zero or negative.

The number of voltage levels and the voltage levels themselves in the pulsing protocol may be chosen arbitrarily as long as the requirements to perform future word read is accomplished. Further, the polarity of the voltages according to the protocols shown may as well be reversed.

Preferably, the word line drivers can be integrated in the area under the matrix and hence not increase to total area of the device.

The segmented word lines could as well be implemented on stacked memory planes, having the bit lines connected vertically to the multiplexers or gate means. This is illustrated in FIG. 8, which shows schematically and in cross section an embodiment wherein memory devices according to the invention are provided in a stacked arrangement. This realizes a volumetric data storage apparatus wherein each layer or memory plane comprises one memory device. By providing the memory devices in a staggered arrangement, the respective word lines and bit lines can be connected over so-called staggered vias, i.e. alternating horizontal and vertical “over-the-edge” connections with driver and control circuitry in the substrate. The substrate can be inorganic, i.e. silicon-based, and hence the circuitry may be implemented in e.g. a compatible CMOS technology. FIG. 8 shows only two memory planes (note that only a limited number of bit line are shown), but in practice the volumetric data storage apparatus may comprise a very large number of memory planes, from 8 and well beyond 100 or more, realizing a memory with very high capacity and storage density, as each memory plane only will be about 1 μm thick or even less.

Advantages of the passive matrix memory device described above include simplicity of manufacture and high density of cells. Further advantages are:

a) During the read cycle all non-addressed memory cells will experience a zero volt potential (or a small potential). This will reduce the number of disturb signals that could result in loss of memory content as well as eliminate all disturbs during a read operation that give rise to sneak currents.

b) The data transfer rate will be at the maximum rate as allowed by the number of bit lines within a segment.

c) The readout voltage V_{S} may be chosen much higher than the coercive voltage without incurring partial switching in non-addressed cells. This allows for switching speeds approaching the highest possible speed of polarizable material in the cells.

d) The readout method is compatible with large matrices.

In addition the memory device of the invention can be realized with a reduced number of sense amplifiers, which is an advantage when the memory is large and also with regard to the power consumption of the sense amplifiers. This can be high, but may also be reduced to some extent by appropriate power management of the driving and addressing circuitry. Moreover, a reduction in the number of sense amplifiers implies that real estate devoted to sense means can be balanced to achieve overall area optimization in the memory device.

Finally, the segmentation of the word lines implies that errors during readout or addressing will be located in a single word in the event of a single word line fault.

1. A non-volatile passive matrix memory device (10) comprising an electrically polarizable dielectric memory material (12) exhibiting hysteresis, particularly a ferroelectric material, wherein said memory material (12) is provide sandwiched in a layer between a first set and second set of respective parallel addressing electrodes, the electrodes of the first set constituting word lines (WL) of the memory device and being provided in substantially orthogonal relationship to the electrodes of the second set, the latter constituting bit lines (BL) of the memory device, wherein a memory cell (13) with a capacitor-like structure is defined in the memory material (12) at crossing between word lines and bit lines, wherein the memory cells of the memory device constitute the elements of the passive matrix, wherein each memory cell can be selectively addressed for a write/read operation via a word line and bit line, wherein a write operation to a memory cell takes place by establishing a desired polarization state in the cell by means of a voltage being applied to the cell via the respective word line and bit line defining the cell, said applied voltage Vs either establishing a determined polarization state in the cell or being able to switch the cell between the polarization states thereof, and wherein a read operation takes place by applying a voltage smaller than the switching or polarization voltage Vs to the cell and detecting at least one electrical parameter of an output current on the bit lines, characterized in that
the word lines are divided into a number of segments, each segment sharing and being defined by a plurality of adjoining bit lines in the matrix, and that means (25) are provided for connecting each bit line assigned to a segment with an associated sensing means, thus enabling the simultaneous connection of all memory cells assigned to a word line on a segment for readout via the corresponding bit lines of the segment, each sensing means being adapted for sensing the charge flow in the associated bit line in order to determine a logical value stored in the memory cell defined by the bit line.

2. A non-volatile passive matrix memory device according to claim 1, characterized in that said means (25) for simultaneous connection of each bit line (BL_{1 . . . n}) of a segment (S_{1 . . . n}) with associated sensing means (SA_{1 . . . n}) during addressing are multiplexers.

3. A non-volatile passive matrix memory device according to claim 2, characterized in that the number of multiplexers corresponds to the largest number of bit lines (BL) defining a segment, each bit line of a segment being connected with a specific multiplexer.

4. A non-volatile passive matrix memory device according to claim 3, characterized in that the output of each multiplexer is connected with a single sensing means.

5. A non-volatile passive matrix memory device according to claim 4, characterized in that the single sensing means is a sense amplifier.

6. A non-volatile passive matrix memory device according to claim 1, characterized in that said means (25) for simultaneous connection of each bit line (BL_{1 . . . n}) of a segment (S_{1 . . . n}) to an associated sensing means (SA_{1 . . . n}) during addressing is a gate means.

7. A non-volatile passive matrix memory device according to claim 6, characterized in that all bit lines of a segment are connected with a specific gate means, each gate means having a number of outputs corresponding to the number of bit lines in the respective segment, that each output of each gate means is connected with a specific bus line of an output data bus, the number of bus lines thus corresponding to largest number of bit lines in a segment, and that each bus line is connected with a single sensing means.

8. A non-volatile passive matrix memory device according to claim 6, characterized in that the gate means (25) comprise pass gates.

9. A non-volatile passive matrix memory device according to claim 7, characterized in that the sensing means is a sense amplifier.

10. A method for readout of a passive non-volatile matrix memory device comprising an electrically polarizable dielectric memory material (12) exhibiting hysteresis, particularly a ferroelectric material, wherein said memory material (12) is provided sandwiched in a layer between a first set and second set of respective parallel addressing electrodes, the electrodes of the first set constituting word lines (WL) of the memory device and being provided in substantially orthogonal relationship to the electrodes of the second set, the latter constituting bit lines (BL) of the memory device, wherein a memory cell (13) with a capacitor-like structure is defined in the memory material (12) at crossing between word lines and bit lines, wherein the memory cells of the memory device constitute the elements of the passive matrix, wherein each memory cell can be selectively addressed for a write/read operation via a word line and bit line, wherein write operation to a memory cell takes place by establishing a desired polarization state in the cell by means of a voltage being applied to the cell via the respective word line and bit line defining the cell, said applied voltage Vs either establishing a determined polarization state in the cell or being able to switch the cell between the polarization states thereof, wherein a read operation takes place by applying a voltage smaller than the switching or polarization voltage Vs to the cell and detecting at least one electrical parameter of an output current or the bit lines, wherein the method comprises steps for controlling electric potentials on all word lines and bit lines in a time-coordinated fashion according to a protocol comprising electric timing sequences for all word lines and bit lines,
arranging said protocol to comprise a read cycle, and
providing during the read cycle for sensing means to sense charges flowing in the bit lines, and wherein the method is characterized by connecting each bit line within a word line segment with an associated sensing means,
activating according to the protocol one word line of the segment at a time by setting the potential of said one word line of the segment to the switching voltage Vs during at least a portion of the read cycle, while keeping all bit lines of the segment at zero potential, and
determining the logical value stored in the individual cells sensed by the sensing means during the read cycle.

11. Method for readout according to claim 10, characterized by
connecting each bit line within a segment with an associated sensing means, keeping all word lines and bit lines, when no cell is read or written, at a quiescent voltage of approximately Vs/3,
activating according to the protocol one word line of the segment at a time by setting the potential of said one word line of the segment to the switching voltage Vs during at least a portion of the read cycle, while keeping all bit lines of the segment at zero potential, and
determining the logical value stored in the individual cells sensed by the sensing means during the read cycle.

12. The use of a non-volatile passive matrix memory device according to claim 1 and a method for readout according to claim 10 in a volumetric data storage apparatus with a plurality of stacked layers, each layer comprising one of the non-volatile passive matrix memory devices.
